(19) United States
(12) Patent Application Publication
(10) Pub. No.: US 2024/0266364 A1
(43) Pub. Date: Aug. 8, 2024

(54) DISPLAY DEVICE AND METHOD OF MANUFACTURING THE SAME

(71) Applicant: Samsung Display Co., LTD., Yongin-si (KR)

(72) Inventors: Mun Soo PARK, Yongin-si (KR); Hui Won YANG, Yongin-si (KR); Sun PARK, Yongin-si (KR)

(73) Assignee: Samsung Display Co., LTD., Yongin-si (KR)

(21) Appl. No.: 18/522,386

(22) Filed: Nov. 29, 2023

(30) Foreign Application Priority Data
Feb. 8, 2023 (KR) 10-2023-0016968

(51) Int. Cl. H01L 27/12; H01L 25/16

(52) U.S. Cl. CPC H01L 27/1248; H01L 25/167; H01L 27/124; H01L 27/1259

(57) ABSTRACT

A display device according to an embodiment including: a base layer including a first surface and a second surface; a first backplane layer disposed on the first surface of the base layer and including a pixel circuit; a second backplane layer disposed on the second surface of the base layer and including a rear wire; and a light-emitting-element layer disposed on the first backplane layer and including a light emitting element. The base layer has a transmittance of about 15% or less with respect to light having a wavelength of about 290 nm or less.

### CROSS-REFERENCE TO RELATED APPLICATION(S)

This application claims priority to and benefits of Korean patent application No. 10-2023-0016968 under 35 U.S.C. § 119, filed on Feb. 8, 2023, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

Recently, as interest in an information display increases, research and development for display devices have been continuously conducted.

### SUMMARY

Embodiments provide a display device and a method of manufacturing the display device capable of reducing a process risk due to light that occurs during a manufacturing process of a display device.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a base layer including a first surface and a second surface; a first backplane layer disposed on the first surface of the base layer and including a pixel circuit; a second backplane layer disposed on the second surface of the base layer and including a rear wire; and a light-emitting-element layer disposed on the first backplane layer and including a light emitting element. The base layer may have a transmittance of about 15% or less with respect to light having a wavelength of about 290 nm or less.

The display device may further include a driving circuit portion electrically connected to the rear wire; a front wire disposed on the first surface of the base layer; and a side wire covering a side surface of the base layer and electrically connected to the front wire and the rear wire.

The rear wire may include a multi-layered member including an aluminum layer.

The base layer may include borosilicate glass doped with a dopant.

The base layer may have a transmittance of about 10% or less with respect to light having a wavelength of about 290 nm or less.

In an embodiment, a display device may include: a base layer including a first surface and a second surface; a first backplane layer disposed on the first surface of the base layer and including a pixel circuit; a second backplane layer disposed on the second surface of the base layer and including a rear wire; and a light-emitting-element layer disposed on the first backplane layer and including a light emitting element. The first backplane layer may be disposed between the pixel circuit and the rear wire, and may include an organic layer having a transmittance of about 10% or less with respect to light having a wavelength of about 290 nm or less.

The organic layer may include polyimide.

The first backplane layer may further include a buffer layer disposed between the pixel circuit and the base layer. The organic layer may be disposed between the buffer layer and the base layer.

The second backplane layer may further include an insulating layer disposed between the rear wire and the base layer. The organic layer may be disposed between the insulating layer and the base layer.

The second backplane layer may further include a rear via layer that is disposed on the base layer and covers a portion of the rear wire. The organic layer may have a first thickness. The rear via layer may have a second thickness. The second thickness may be greater than the first thickness.

The first thickness may be about 0.5 μm to about 2.0 μm.

In an embodiment, a method of manufacturing a display device may include: preparing a base layer including a first surface and a second surface; forming a first backplane layer on the first surface of the base layer; and forming a second backplane layer on the second surface of the base layer. The base layer may have a transmittance of about 15% or less with respect to light having a wavelength of about 290 nm or less.

The method of manufacturing may further include, after forming the first backplane layer, reversing the base layer and the first backplane layer such that the first surface of the base layer faces downward based on a direction of gravity.

The forming of the first backplane layer may include disposing a buffer layer on the first surface of the base layer; and forming a transistor including a semiconductor layer on the buffer layer.

The forming of the second backplane layer may include forming an insulating layer on the second surface of the base layer; and forming a rear wire on the insulating layer. The forming of the rear wire may include performing a dry etching process by using Cl₂ plasma.

The performing of the dry etching process may include emitting UV light on the insulating layer.

The base layer may not transmit at least a portion of the UV light emitted on the insulating layer.

The forming of the second backplane layer may include forming an insulating layer on the second surface of the base layer; and forming a rear wire on the insulating layer. The forming of the rear wire may include performing a wet etching process.

The forming of the first backplane layer may include disposing an organic layer on the first surface of the base layer and disposing a buffer layer on the organic layer.

The forming of the second backplane layer may include disposing an organic layer on the second surface of the base layer and disposing an insulating layer on the organic layer.

According to an embodiment, it is possible to provide a display device and a method of manufacturing thereof capable of reducing a process risk due to light that occurs during a manufacturing process of a display device.

### BRIEF DESCRIPTION OF THE DRAWINGS

FIG. 1 illustrates a top schematic plan view of a display device according to an embodiment.

FIG. 2 illustrates an example of a pixel of FIG. 1.

FIG. 3 illustrates a schematic cross-sectional view of a display device according to an embodiment.

FIG. 4, FIG. 6, and FIG. 7 illustrate schematic cross-sectional views of a base layer and a backplane layer according to an embodiment.

FIG. 5 illustrates a schematic cross-sectional view of a rear wire according to an embodiment.

FIG. 8 illustrates a schematic cross-sectional view of a display device according to an embodiment.

FIG. 9 illustrates a schematic cross-sectional view of a portion of a non-display area of a display device according to an embodiment.

FIG. 10 illustrates a schematic cross-sectional view of a display area and a non-display area of a display device according to an embodiment.

FIG. 11 illustrates a flowchart of a method of manufacturing a display device according to an embodiment.

FIG. 12 to FIG. 17 illustrate schematic cross-sectional views of process phases of a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

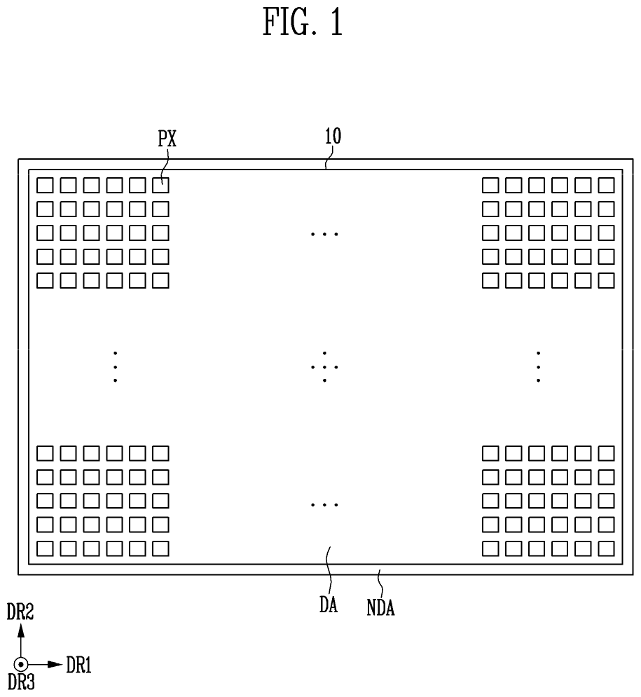

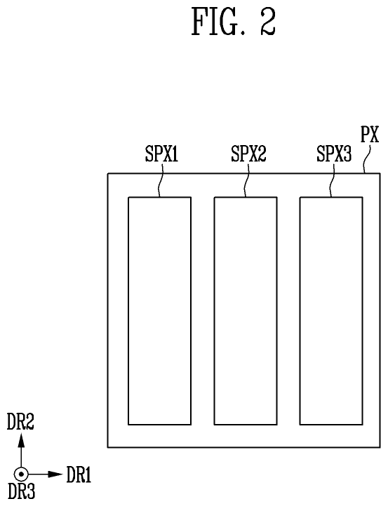

Referring to FIG. 1 to FIG. 10, a display device 10 will be described according to an embodiment. FIG. 1 illustrates a top plan view of a display device according to an embodiment. FIG. 2 illustrates an example of a pixel of FIG. 1.

Referring to FIG. 1, the display device 10 may output light information. For example, the display device 10 may be a device for displaying moving images or still images, and may be applied to various devices. The display device 10 may be formed as a flat surface having a rectangular shape having a long side of a first direction DR1 and a short side of a second direction DR2 crossing the first direction DR1. A corner at which the long side of the first direction DR1 and the short side of the second direction DR2 meet may be rounded to have a predetermined curvature or may be formed to have a right angle. The flat shape of the display device 10 is not limited to a quadrangular shape, and may be formed to have another polygonal, circular, or elliptical shape. The display device 10 may be formed to be flat, but embodiments are not limited thereto. For example, the display device 10 may include curved portions that are formed at left and right end portions and have a constant curvature or a variable curvature. For example, the display device 10 may be flexibly formed to be bendable, curvable, foldable, or rollable.

The display device 10 may further include pixels PX, scan wires extending in the first direction DR1, and data wires extending in the second direction DR2, to display an image. The pixels PX may be arranged in a matrix format in the first direction DR1 and the second direction DR2.

The display device 10 may include a display area DA and a non-display area NDA. In some embodiments, the non-display area NDA may be disposed around the display area DA. The non-display area NDA may surround at least a portion of the display area DA.

The pixel PX may be disposed in the display area DA. The pixel PX may not be disposed in the non-display area NDA. Each of the pixels PX may include sub-pixels SPX1, SPX2, and SPX3 as shown in FIG. 2. FIG. 2 illustrates that each of the pixels PX includes three sub-pixels SPX1, SPX2, and SPX3, e.g., a first sub-pixel SPX1, a second sub-pixel SPX2, and a third sub-pixel SPX3, but embodiments are not limited thereto.

The first sub-pixel SPX1, the second sub-pixel SPX2, and the third sub-pixel SPX3 may be connected to at least one of the data wires and at least one of the scan wires.

Each of the first sub-pixel SPX1, the second sub-pixel SPX2, and the third sub-pixel SPX3 may have a rectangular shape, a square shape, or rhombus planar shape. For example, each of the first sub-pixel SPX1, the second sub-pixel SPX2, and the third sub-pixel SPX3 may have a rectangular planar shape having short sides in the first direction DR1 and long sides in the second direction DR2 as shown in FIG. 2. In some embodiments, each of the first sub-pixel SPX1, the second sub-pixel SPX2, and the third sub-pixel SPX3 may also have a square or rhombus planar shape including sides having a same length in the first direction DR1 and the second direction DR2.

As shown in FIG. 2, the first sub-pixel SPX1, the second sub-pixel SPX2, and the third sub-pixel SPX3 may be arranged in the first direction DR1. In another example, one of the second sub-pixel SPX2 and the third sub-pixel SPX3 and the first sub-pixel SPX1 may also be arranged in the first direction DR1, and the other thereof and the first sub-pixel SPX1 may be arranged in the second direction DR2.

In another example, one of the first sub-pixel SPX1 and the third sub-pixel SPX3 and the second sub-pixel SPX2 may be arranged in the first direction DR1, and the other thereof and the second sub-pixel SPX2 may be arranged in the second direction DR2. In another example, one of the first sub-pixel SPX1 and the second sub-pixel SPX2 and the third sub-pixel SPX3 may be arranged in the first direction DR1, and the other thereof and the third sub-pixel SPX3 may be arranged in the second direction DR2.

The first sub-pixel SPX1 may emit first light, the second sub-pixel SPX2 may emit second light, and the third sub-pixel SPX3 may emit third light. For example, the first light may be light of a red wavelength band, the second light may be light of a green wavelength band, and the third light may be light of a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm, but embodiments are not limited thereto.

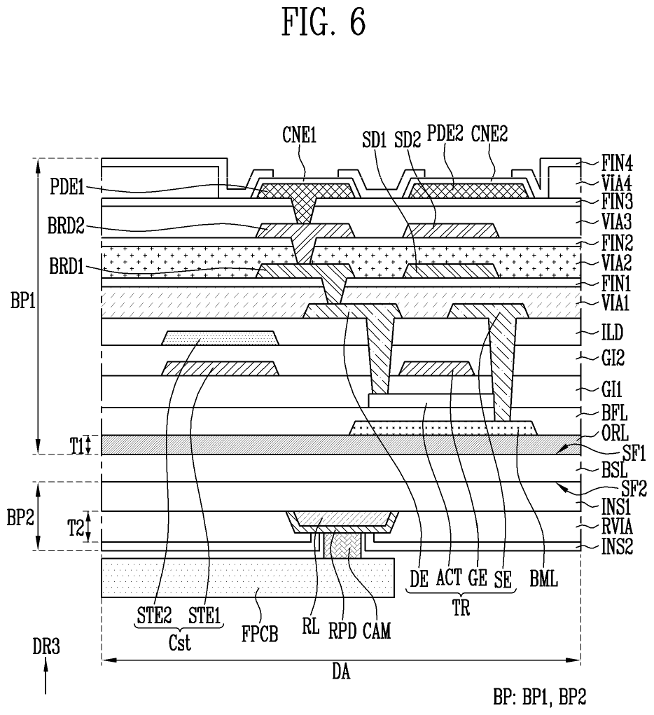

Each of the first sub-pixel SPX1, the second sub-pixel SPX2, and the third sub-pixel SPX3 may be a light emitting element LE (see FIG. 8) emitting light, and may include an inorganic light emitting element including an inorganic semiconductor.

As shown in FIG. 2, an area of the first sub-pixel SPX1, an area of the second sub-pixel SPX2, and an area of the third sub-pixel SPX3 may be substantially same as each other, but embodiments are not limited thereto. At least one of the area of the first sub-pixel SPX1, the area of the second sub-pixel SPX2, and the area of the third sub-pixel SPX3 may be different from another one thereof. In another example, two of the area of the first sub-pixel SPX1, the area of the second sub-pixel SPX2, and the area of the third sub-pixel SPX3 may be substantially same as each other, and the other one thereof may be different from the two. In another example, the area of the first sub-pixel SPX1, the area of the second sub-pixel SPX2, and the area of the third sub-pixel SPX3 may be different from each other.

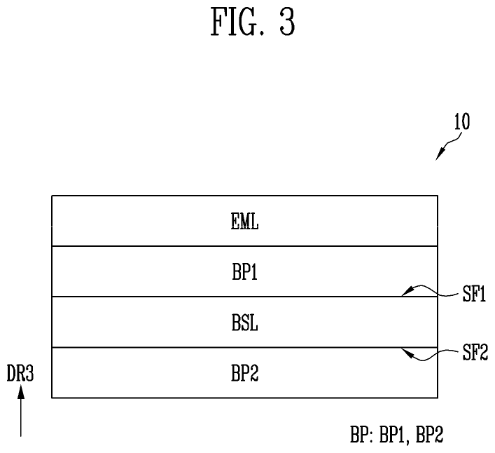

FIG. 3 illustrates a schematic cross-sectional view of a display device according to an embodiment.

Referring to FIG. 3, the display device 10 according to an embodiment may include a base layer BSL, a backplane layer BP, and a light-emitting-element layer EML.

The base layer BSL may be a base substrate or a base member for supporting the display device 10. The base layer BSL may be a rigid substrate made of a glass material. In another example, the base layer BSL may be a flexible substrate that is bendable, foldable, or rollable. For example, the substrate may include an insulating material such as a polymer resin such as a polyimide.

The backplane layer BP may include metal layers for forming pixel circuits and wires, and insulating layers disposed between the metal layers.

In some embodiments, the backplane layer BP may include a first backplane layer BP1 and a second backplane layer BP2. The first backplane layer BP1 and the second backplane layer BP2 may be disposed on sides (e.g., opposite sides) of the base layer BSL, respectively.

In some embodiments, the first backplane layer BP1 may be a pixel circuit layer. The second backplane layer BP2 may be a rear wire layer.

The first backplane layer BP1 may be a layer including a pixel circuit for driving the pixel PX. The first backplane layer BP1 may be disposed on a first surface (for example, a front surface) SF1 of the base layer BSL. In some embodiments, the first backplane layer BP1 may be disposed between the base layer BSL and the light-emitting-element layer EML.

The pixel circuits may include thin film transistors. The pixel circuits may further include storage capacitors. The pixel circuits may be connected (e.g., electrically connected) to the light emitting elements LE to provide electrical signals for the light emitting elements LE to emit light.

The second backplane layer BP2 may include a second backplane layer BP2 including rear wires connected (e.g., electrically connected) to a driving circuit portion FPCB. The second backplane layer BP2 may be disposed on a second surface (for example, a rear surface) SF2 of the base layer BSL. The second surface SF2 may be an opposite surface of the first surface SF1.

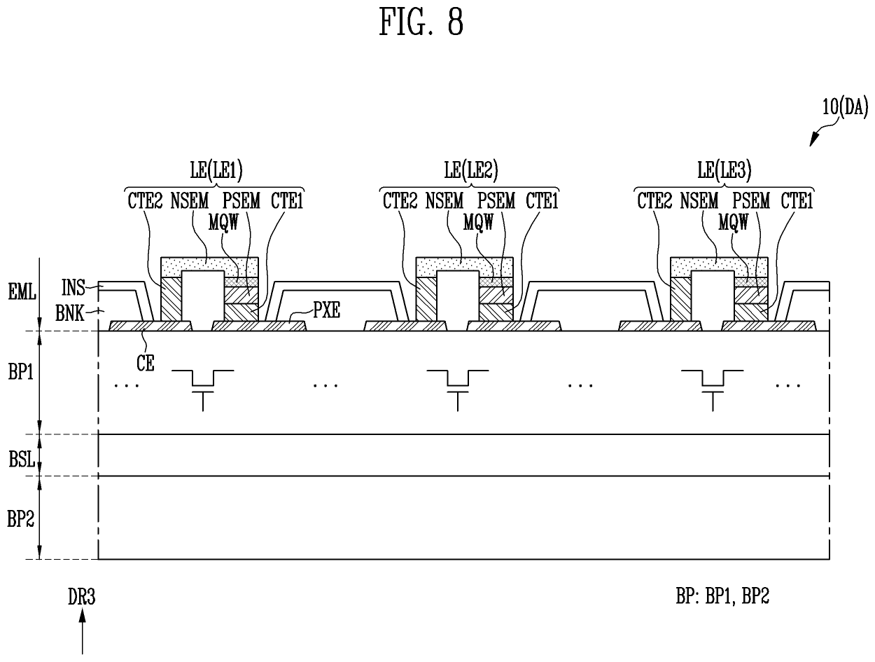

Wires formed on the second backplane layer BP2 may be connected (e.g., electrically connected) to the driving circuit portion FPCB. The wires formed on the second backplane layer BP2 may provide electrical signals provided from the driving circuit portion FPCB to front wires FL (see FIG. 10) of the first backplane layer BP1 through side wires SL (see FIG. 10).

The light-emitting-element layer EML may be disposed on the first backplane layer BP1. The light-emitting-element layer EML may include a light emitting element LE that emits light based on a signal provided from a pixel circuit of the first backplane layer BP1.

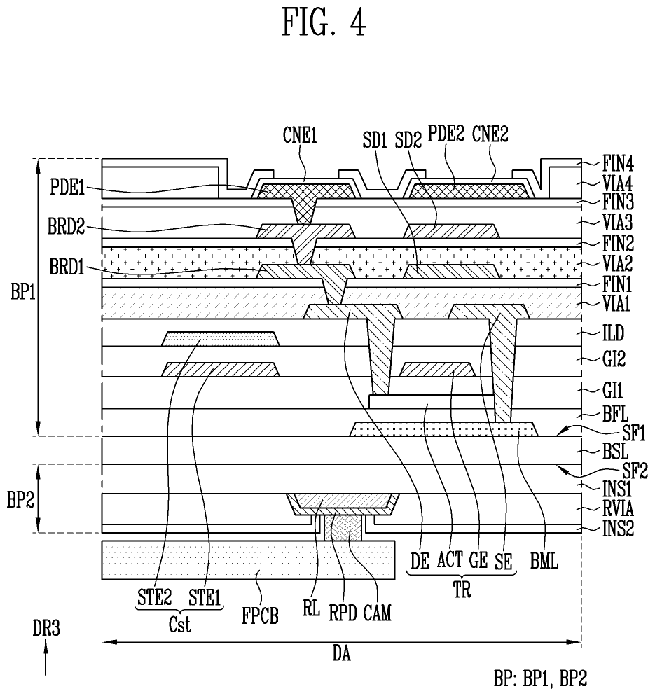

A more detailed cross-sectional structure of the backplane layer BP according to an embodiment will be described with reference to FIG. 4 to FIG. 7.

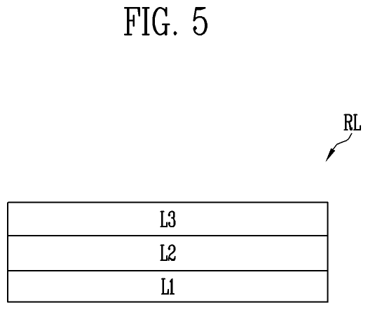

FIG. 4, FIG. 6, and FIG. 7 illustrate schematic cross-sectional views of a base layer and a backplane layer according to an embodiment. FIG. 4, FIG. 6, and FIG. 7 illustrate a cross-sectional structure in a partial area of the display area DA. FIG. 5 illustrates a schematic cross-sectional view of a rear wire according to an embodiment.

FIG. 4 illustrates a backplane layer BP of the display device 10 according to a first embodiment. The display device 10 according to the first embodiment will be described with reference to FIG. 4 and FIG. 5.

According to an embodiment, the first backplane layer BP1 may include a lower metal layer BML, a transistor TR, a storage capacitor Cst, a first bridge electrode BRD1, a first data electrode SD1, a second bridge electrode BRD2, a second data electrode SD2, a first pixel electrode PDE1, a second pixel electrode PDE2, a first connection electrode CNE1, a second connection electrode CNE2, and insulating layers BFL, GI1, GI2, ILD, VIA1, VIA2, VIA3, VIA4, FIN1, FIN2, FIN3, and FIN4, which are disposed on the first surface SF1 of the base layer BSL.

The base layer BSL may form a base on which the backplane layer BP is disposed.

The base layer BSL according to the first embodiment may have non-transmittance to light in a UV wavelength band. The base layer BSL according to the first embodiment may non-transmit (or may not transmit) at least some of the light in the UV wavelength band. For example, the base layer BSL may have a transmittance of about 15% or less with respect to light having a wavelength of about 290 nm or less. For example, the base layer BSL may have a transmittance of about 10% or less with respect to light having a wavelength of about 290 nm or less.

In some embodiments, the base layer BSL may include a material having excellent light blocking performance for light in a UV wavelength band. For example, the base layer BSL may include a glass material that satisfies the above-described optical performance (for example, transmission condition). In some embodiments, the base layer BSL may include borosilicate glass. In some embodiments, in order to manufacture the base layer BSL having a certain transmittance, a dopant capable of adjusting transmittance may be further doped into a glass material for forming the base layer BSL. The transmittance of the base layer BSL may be controlled by adjusting the amount of the dopant doped into the base layer BSL. The dopant may include at least one of tungsten (W), cerium (Ce), and niobium (Nb). However, embodiments are not limited thereto.

In some embodiments, various methods may be used to control the transmittance of the base layer BSL. For example, in order for the base layer BSL to be provided to satisfy the above-described transmission conditions, the process environment temperature may be controlled during the manufacturing process of the display device 10. In some embodiments, in order for the base layer BSL to be provided to satisfy the above-described transmission conditions, the concentration of defects in the base layer BSL may be controlled.

Experimentally, in case that a process for manufacturing the second backplane layer BP2 is performed, light in a UV wavelength band may be generated.

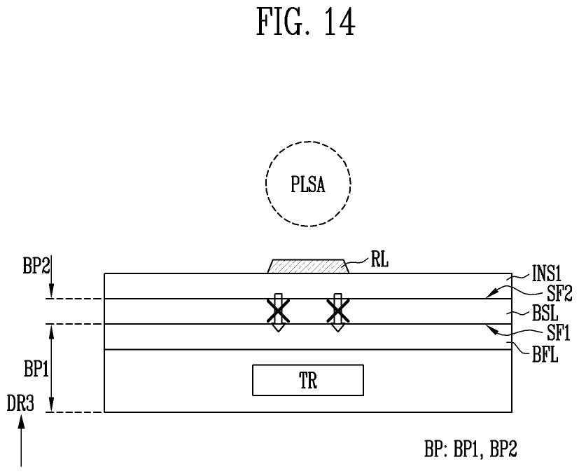

For example, in case that a rear wire RL in the second backplane layer BP2 has a conductive structure/member including aluminum (Al), the rear wiring RL may be manufactured by patterning an aluminum layer formed after depositing the aluminum layer through dry etching using Cl₂ plasma (PLSA) (see FIG. 14). For example, the aluminum material for aluminum deposition may be ionized in case that the Cl₂ plasma (PLSA) is applied, and electron-hole pairs may be formed. For example, the formed electron-hole pairs may recombine with each other, and light in the UV wavelength band may be emitted. For example, the emitted UV wavelength band may be about 260 nm to about 270 nm.

As another example, in case that a first insulating layer INS1 in the second backplane layer BP2 includes a silicon nitride (SiNₓ) or the like, due to the Cl₂ plasma (PLSA), the silicon nitride (SiNₓ) may be ionized and electron-hole pairs may be formed. For example, the electron-hole pairs may recombine with each other in the first insulating layer INS1, and light in the UV wavelength band may be emitted. For example, the emitted UV wavelength band may be about 280 to about 290 nm.

The UV light may affect the operating performance of components in the first backplane layer BP1. For example, in case that the UV light is applied to a semiconductor layer ACT of the transistor TR, a threshold voltage of the transistor TR may be shifted from an intended range.

According to an embodiment, the base layer BSL may block at least some of light in a UV wavelength band. For example, in case that the second backplane layer BP2 is manufactured, the generated UV light may not be excessively applied to the first backplane layer BP1. Accordingly, the influence of UV light on the semiconductor layer ACT may be reduced, and accordingly, the reliability of an electrical signal to be supplied to the light emitting element LE may be improved. For example, since the degree, to which UV light is applied to the semiconductor layer ACT, is substantially reduced, the risk of shifting the threshold voltage of the transistor TR may be reduced.

The lower metal layer BML may include a conductive material and may be disposed on the base layer BSL. In some embodiments, the lower metal layer BML may include one or more of copper (Cu), molybdenum (Mo), tungsten (W), aluminum neodymium (AlNd), titanium (Ti), aluminum (Al), silver (Ag), and an alloy thereof. However, embodiments are not limited thereto.

In some embodiments, the lower metal layer BML may overlap the transistor TR in a plan view. For example, the lower metal layer BML may overlap the semiconductor layer ACT in a plan view.

In some embodiments, the lower metal layer BML may be connected (e.g., electrically connected) to a source electrode SE. For example, the lower metal layer BML may be connected (e.g., electrically connected) to the source electrode SE through a contact member penetrating the first gate insulating layer GI1, the second gate insulating layer GI2, and the interlayer insulating layer ILD. A source signal (for example, an anode signal supplied to the light emitting element LE) of the transistor TR may be supplied to both the source electrode SE and the lower metal layer BML. For example, the source signal of the transistor TR may be simultaneously supplied to the source electrode SE and the lower metal layer BML, and excessive fluctuation of the threshold voltage of the transistor TR may be alleviated.

The buffer layer BFL may be disposed on the base layer BSL and the lower metal layer BML. The buffer layer BFL may prevent diffusion of impurities or the like into a circuit element (for example, the transistor TR). The buffer layer BFL may include an inorganic material.

For example, the buffer layer BFL may include one or more of a silicon nitride (SiNₓ), a silicon oxide (SiOₓ), a silicon oxynitride (SiOₓN_{y}), and an aluminum oxide (AlₓO_{y}).

In some embodiments, the buffer layer BFL may not include nitride. For example, the buffer layer BFL may not include a silicon nitride (SiNₓ), and may include one or more of a silicon oxide (SiOₓ), a silicon oxynitride (SiOₓN_{y}), and an aluminum oxide (AlₓO_{y}).

Experimentally, in case that Cl₂ plasma PLSA is used during the manufacturing process of the second backplane layer BP2, the material in the buffer layer BFL may be ionized to form electron-hole pairs. In case that the buffer layer BFL includes silicon nitride (SiNₓ), defects (for example, dangling bonds) may occur in the structure of silicon nitride (SiNₓ). The silicon nitride (SiNₓ) may have more defects and a relatively large number of holes than other inorganic materials (for example, a silicon oxide SiOₓ). For example, in case that a dry etching process using Cl₂ plasma PLSA is performed during the manufacturing process of the display device 10, an electric field for forming plasma PLSA may be formed. For example, holes and a small amount of electrons may be trapped in the buffer layer BFL including the silicon nitride (SiNₓ) due to the formed electric field. Experimentally, in case that the holes are trapped in the buffer layer BFL, there is a risk that the trapped holes shift the threshold voltage of the transistor TR. However, according to an embodiment, the buffer layer BFL may not include silicon nitride SiNₓ, and thus, the amount of defects formed in the buffer layer BFL may be small, and the risk due to the defects may be reduced. As a result, the reliability of electrical signals in the first backplane layer BP1 may be improved.

The transistor TR may include a semiconductor layer ACT, a source electrode SE, a drain electrode DE, and a gate electrode GE. In some embodiments, the transistor TR may include a driving transistor. In some embodiments, the transistor TR may further include a switching transistor.

The semiconductor layer ACT, the source electrode SE, and the drain electrode DE may be disposed on the buffer layer BFL.

The semiconductor layer ACT may be an area overlapping the gate electrode GE, and may include a channel area, a first source area, and a first drain area of the transistor TR. The first source area may be a partial area of the semiconductor layer ACT, and may be electrically and/or physically connected to the source electrode SE through contact holes of the insulating layers GI1, GI2, and ILD. The first drain area may be a partial area of the semiconductor layer ACT, and may be electrically and/or physically connected to the drain electrode DE through contact holes of the insulating layers GI1, GI2, and ILD.

The semiconductor layer ACT may include one or more of a polysilicon, a low temperature polycrystalline silicon (LTPS), an amorphous silicon, and an oxide semiconductor. For example, the source area and the drain area may be formed of a semiconductor layer doped with an impurity, and the channel area may be formed of a semiconductor layer that is not doped with an impurity. For example, an n-type impurity may be used as the impurity, but embodiments are not limited thereto.

The gate electrode GE may include a conductive material, and may be disposed on the first gate insulating layer GI1. The gate electrode GE may overlap the semiconductor layer ACT in a plan view. For example, the gate electrode GE may include one or more of copper (Cu), molybdenum (Mo), tungsten (W), aluminum neodymium (AlNd), titanium (Ti), aluminum (Al), silver (Ag), and an alloy thereof. However, embodiments are not limited thereto.

The first gate insulating layer GI1 may be disposed on the buffer layer BFL and the semiconductor layer ACT. The first gate insulating layer GI1 may include an inorganic material. For example, the first gate insulating layer GI1 may include one or more of a silicon nitride (SiNₓ), a silicon oxide (SiOx), a silicon oxynitride (SiOₓN_{y}), and an aluminum oxide (AlₓO_{y}). However, embodiments are not limited to the example described above.

A first storage electrode STE1 may be disposed on the first gate insulating layer GI1.

The second gate insulating layer GI2 may be disposed on the first gate insulating layer GI1, the gate electrode GE, and the first storage electrode STE1. The second gate insulating layer GI2 may include an inorganic material. For example, the second gate insulating layer GI2 may include one or more of a silicon nitride (SiNₓ), a silicon oxide (SiOₓ), a silicon oxynitride (SiOₓN_{y}), and an aluminum oxide (AlₓO_{y}). However, embodiments are not limited to the example described above.

A second storage electrode STE2 may be disposed on the second gate insulating layer GI2. The second storage electrode STE2 may overlap the first storage electrode STE1 to form the storage capacitor Cst together with the first storage electrode STE1.

The interlayer insulating layer ILD may be disposed on the second gate insulating layer GI2 and the second storage electrode STE2. The interlayer insulating layer ILD may include an inorganic material. For example, the interlayer insulating layer ILD may include one or more of a silicon nitride (SiNₓ), a silicon oxide (SiOₓ), a silicon oxynitride (SiOₓN_{y}), and an aluminum oxide (AlₓO_{y}). However, embodiments are not limited to the example described above.

The source electrode SE and the drain electrode DE may be disposed on the interlayer insulating layer ILD. The source electrode SE may be electrically and/or physically connected to the source area of the semiconductor layer ACT through a contact member penetrating the interlayer insulating layer ILD, the second gate insulating layer GI2, and the first gate insulating layer GI1, and the drain electrode DE may be electrically and/or physically connected to the drain area of the semiconductor layer ACT through a contact member penetrating the interlayer insulating layer ILD, the second gate insulating layer GI2, and the first gate insulating layer GI1. The drain electrode DE may be electrically and/or physically connected to a first bridge electrode BRD1 described below. For example, the source electrode SE and the drain electrode DE may include a single layered structure/member formed a single or mixture of copper (Cu), molybdenum (Mo), tungsten (W), aluminum neodymium (AlNd), titanium (Ti), aluminum (Al), silver (Ag), and an alloy thereof and of a mixture thereof, and may include a double-layered structure/member or a triple-layered structure/member further including molybdenum (Mo), titanium (Ti), copper (Cu), aluminum (Al), or silver (Ag). However, embodiments are not limited to the example described above.

The first via layer VIA1 may be disposed on the source electrode SE and the drain electrode DE. The first via layer VIA1 may include at least one organic insulating layer. The first via layer VIA1 may be formed as a single layer or a multilayer, and may include an inorganic insulating material and an organic insulating material. For example, the first via layer VIA1 may include at least one of an acrylic resin, an epoxy resin, a phenol resin, a polyamide resin, and a polyimide resin. However, embodiments are not limited thereto.

The first front insulating layer FIN1 may be disposed on the first via layer VIA1. The first front insulating layer FIN1 may include an inorganic material. For example, the first front insulating layer FIN1 may include one or more of a silicon nitride (SiNₓ), a silicon oxide (SiOₓ), a silicon oxynitride (SiOₓN_{y}), and an aluminum oxide (AlₓO_{y}). However, embodiments are not limited to the example described above.

The first bridge electrode BRD1 and the first data electrode SD1 may be disposed on the first front insulating layer FIN1. The first bridge electrode BRD1 may be electrically and/or physically connected to the drain electrode DE through a contact member formed on the first front insulating layer FIN1 and the first via layer VIA1. For example, the first data electrode SD1 may correspond to a data line, a driving voltage line, a driving low voltage line, and the like. The first bridge electrode BRD1 and the first data electrode SD1 may include a single layered structure/member formed a single or mixture of copper (Cu), molybdenum (Mo), tungsten (W), aluminum neodymium (AlNd), titanium (Ti), aluminum (Al), silver (Ag), and an alloy thereof and of a mixture thereof, and may include a double-layered structure/member or a triple-layered structure/member further including molybdenum (Mo), titanium (Ti), copper (Cu), aluminum (Al), or silver (Ag).

The second via layer VIA2 may be disposed on the first front insulating layer FIN1, the first bridge electrode BRD1, and the first data electrode SD1. The second via layer VIA2 may include at least one organic insulating layer. The second via layer VIA2 may be formed as a single layer or a multilayer, and may include an inorganic insulating material and an organic insulating material. For example, the second via layer VIA2 may include at least one of an acrylic resin, an epoxy resin, a phenol resin, a polyamide resin, and a polyimide resin. However, embodiments are not limited thereto.

The second front insulating layer FIN2 may be disposed on the second via layer VIA2. The second front insulating layer FIN2 may include an inorganic material. For example, the second front insulating layer FIN2 may include one or more of a silicon nitride (SiNₓ), a silicon oxide (SiOₓ), a silicon oxynitride (SiOₓN_{y}), and an aluminum oxide (AlₓO_{y}). However, embodiments are not limited to the example described above.

The second bridge electrode BRD2 and the second data electrode SD2 may be disposed on the second front insulating layer FIN2. The second bridge electrode BRD2 may be electrically and/or physically connected to the first bridge electrode BRD1 through a contact member formed on the second front insulating layer FIN2 and the second via layer VIA2. For example, the second data electrode SD2 may correspond to a data line, a driving voltage line, a driving low voltage line, and the like. The second bridge electrode BRD2 and the second data electrode SD2 may include a single layered structure/member formed a single or mixture of copper (Cu), molybdenum (Mo), tungsten (W), aluminum neodymium (AlNd), titanium (Ti), aluminum (Al), silver (Ag), and an alloy thereof and of a mixture thereof, and may include a double-layered structure/member or a triple-layered structure/member further including molybdenum (Mo), titanium (Ti), copper (Cu), aluminum (Al), or silver (Ag).

The third via layer VIA3 may be disposed on the second front insulating layer FIN2, the second bridge electrode BRD2, and the second data electrode SD2. The third via layer VIA3 may include at least one organic insulating layer. The third via layer VIA3 may be formed as a single layer or a multilayer, and may include an inorganic insulating material and an organic insulating material. For example, the third via layer VIA3 may include at least one of an acrylic resin, an epoxy resin, a phenol resin, a polyamide resin, and a polyimide resin. However, embodiments are not limited thereto.

The third front insulating layer FIN3 may be disposed on the third via layer VIA3. The third front insulating layer FIN3 may include an inorganic material. For example, the third front insulating layer FIN3 may include one or more of a silicon nitride (SiNₓ), a silicon oxide (SiOₓ), a silicon oxynitride (SiOₓN_{y}), and an aluminum oxide (AlₓO_{y}). However, embodiments are not limited to the example described above.

The first pixel electrode PDE1 may be disposed on the third front insulating layer FIN3, and may contact the upper surface of the second bridge electrode BRD2 exposed by the third front insulating layer FIN3 and the third via layer VIA3. Accordingly, the first pixel electrode PDE1 may be electrically and/or physically connected to the second bridge electrode BRD2, and may be connected (e.g., electrically connected) to the drain electrode DE through the second bridge electrode BRD2 and the first bridge electrode BRD1. The first pixel electrode PDE1 may be connected (e.g., electrically connected) to a pixel electrode PXE (see FIG. 8) of the light emitting element LE.

The second pixel electrode PDE2 may be disposed on the third front insulating layer FIN3. The second pixel electrode PDE2 and the first pixel electrode PDE1 may include a single layered structure/member formed a single or mixture of copper (Cu), molybdenum (Mo), tungsten (W), aluminum neodymium (AlNd), titanium (Ti), aluminum (Al), silver (Ag), and an alloy thereof and of a mixture thereof, and may include a double-layered structure/member or a triple-layered structure/member further including molybdenum (Mo), titanium (Ti), copper (Cu), aluminum (Al), or silver (Ag). The second pixel electrode PDE2 may be connected (e.g., electrically connected) to a cathode CE (see FIG. 8) of the light emitting element LE.

The first connection electrode CNE1 may be disposed on the first pixel electrode PDE1 to cover the first pixel electrode PDE1. The second connection electrode CNE2 may be disposed on the second pixel electrode PDE2 to cover the second pixel electrode PDE2. The first connection electrode CNE1 and the second connection electrode CNE2 may include a transparent conductive oxide. For example, the first connection electrode CNE1 and the second connection electrode CNE2 may include an indium tin oxide (ITO), an indium zinc oxide (IZO), a zinc oxide (ZnO), an indium gallium zinc oxide (IGZO), and an indium tin zinc oxide (ITZO).

The fourth via layer VIA4 may be disposed on a portion of the third front insulating layer FIN3. The fourth via layer VIA4 may expose the upper surface of the first connection electrode CNE1 and the upper surface of the second connection electrode CNE2. The fourth via layer VIA4 may be formed as a single layer or a multilayer, and may include an inorganic insulating material and an organic insulating material. For example, the fourth via layer VIA4 may include at least one of an acrylic resin, an epoxy resin, a phenol resin, a polyamide resin, and a polyimide resin. However, embodiments are not limited thereto.

The fourth front insulating layer FIN4 may be disposed on the fourth via layer VIA4, the first connection electrode CNE1, and the second connection electrode CNE2. The fourth front insulating layer FIN4 may be disposed to expose a portion of the upper surface of the first connection electrode CNE1 and a portion of the upper surface of the second connection electrode CNE2. The exposed portion of the upper surface of the first connection electrode CNE1 may be connected (e.g., electrically connected) to the pixel electrode PXE, and the exposed portion of the upper surface of the second connection electrode CNE2 may be connected (e.g., electrically connected) to the cathode CE.

The second backplane layer BP2 may include a rear wire RL, a rear pad electrode RPD, a first insulating layer INS1, a second insulating layer INS2, and a rear via layer RVIA that are disposed on the second surface SF2 of the base layer BSL.

The first insulating layer INS1 may be disposed on the second surface SF2 of the base layer BSL. The first insulating layer INS1 may include an inorganic material (or substance). For example, the first insulating layer INS1 may include a transparent inorganic insulating material in order to align wires and the like.

The rear wire RL may be disposed on the first insulating layer INS1. The rear wire RL may include a single layered structure/member formed a single or mixture of copper (Cu), molybdenum (Mo), tungsten (W), aluminum neodymium (AlNd), titanium (Ti), aluminum (Al), silver (Ag), and an alloy thereof and of a mixture thereof, and may include a double-layered structure/member or a triple-layered structure/member further including molybdenum (Mo), titanium (Ti), copper (Cu), aluminum (Al), or silver (Ag).

For example, the rear wire RL may have a multi-layered structure/member in which a first layer L1, a second layer L2, and a third layer L3 are sequentially stacked (see FIG. 5). For example, the first layer L1 and the third layer L3 may include titanium (Ti), and the second layer L2 may include aluminum (Al). For example, a dry etching process may be performed to pattern the second layer L2. In some embodiments, the first layer L1 and the third layer L3 may include titanium (Ti), and the second layer L2 may include other metal materials (for example, copper (Cu), molybdenum (Mo), and the like) without including aluminum (Al). For example, a dry etching process may be performed to pattern the second layer L2.

The rear pad electrode RPD may be disposed on the rear wire RL. The rear pad electrode RPD may be disposed on the rear wire RL and the first insulating layer INS1 to cover the rear wire RL.

The second insulating layer INS2 may be disposed on the rear pad electrode RPD. The second insulating layer INS2 may cover the rear pad electrode RPD to expose at least a portion of the upper surface of the rear pad electrode RPD, and may cover the first insulating layer INS1. A conductive adhesive member CAM may be disposed on the upper surface of the rear pad electrode RPD exposed by the second insulating layer INS2. The rear pad electrode RPD may be connected (e.g., electrically connected) to the driving circuit portion FPCB through the conductive adhesive member CAM.

The conductive adhesive member CAM may be an anisotropic conductive film or an anisotropic conductive paste. The driving circuit portion FPCB may include a flexible circuit board. The driving circuit portion FPCB may include a source driving circuit for supplying data voltages to data wires.

The second insulating layer INS2 may include an inorganic material. For example, the second insulating layer INS2 may include one or more of a silicon nitride (SiNₓ), a silicon oxide (SiOₓ), a silicon oxynitride (SiOₓN_{y}), and an aluminum oxide (AlₓO_{y}). However, embodiments are not limited to the example described above.

In some embodiments, the rear via layer RVIA may be disposed between the first insulating layer INS1 and the second insulating layer INS2. The rear via layer RVIA may be disposed on the first insulating layer INS1, and may be disposed to cover the rear wire RL and the rear pad electrode RPD. The rear via layer RVIA may be disposed to cover the rear pad electrode RPD so as to expose at least a portion of the upper surface of the rear pad electrode RPD. The rear via layer RVIA may be formed as a single layer or a multilayer, and may include an inorganic insulating material and an organic insulating material. For example, the rear via layer RVIA may include at least one of an acrylic resin, an epoxy resin, a phenol resin, a polyamide resin, and a polyimide resin. However, embodiments are not limited thereto.

The display device 10 according to the second embodiment will be described with reference to FIG. 6 and FIG. 7. Descriptions that are redundant to those described above are simplified or are not repeated for descriptive convenience. FIG. 6 and FIG. 7 illustrate a backplane layer BP of the display device 10 according to the second embodiment.

The display device 10 according to the second embodiment is different from the display device 10 according to the first embodiment in that it further includes an organic layer ORL.

The organic layer ORL may be disposed between the base layer BSL and the rear wire RL, and may include an organic material. For example, UV light that occurs during the process for patterning the rear wire RL may be non-transmitted, so that the UV light may not be excessively applied to at least a portion (for example, the transistor TR) of the first backplane layer BP1. Accordingly, the organic layer ORL may eliminate a risk caused by occurrence of the UV light.

In some embodiments, the organic layer ORL may include an organic material. For example, the organic layer ORL may include polyimide. The organic layer ORL may have a transmittance of about 10% or less with respect to light having a wavelength of about 290 nm or less. For example, the organic layer ORL may have a transmittance of about 5% or less with respect to light having a wavelength of about 290 nm or less.

In some embodiments, the organic layer ORL may have a thinner thickness than the rear via layer RVIA. For example, the organic layer ORL may have a first thickness T1, and the rear via layer RVIA may have a second thickness T2. The second thickness T2 may be greater than the first thickness T1. In some embodiments, the rear via layer RVIA may be a planarization layer. The organic layer ORL may be a functional layer for transmitting UV light. For example, the first thickness T1 may be about 0.5 μm to about 2.0 μm. In case that the first thickness T1 is less than about 0.5 μm, the organic layer ORL may not sufficiently block UV light, and in case that the first thickness T1 is greater than about 2.0 μm, the organic layer ORL has sufficient non-transmitting characteristics. For example, since the thickness of the organic layer ORL is excessively increased, process costs may be unnecessarily required. The second thickness T2 may be greater than or equal to about 3 μm. In case that the second thickness T2 is smaller than about 3 μm, it may be difficult to sufficiently achieve a planarization function.

In some embodiments, the organic layer ORL may be disposed between the base layer BSL and the buffer layer BFL (see FIG. 6). For example, the organic layer ORL may be included in the first backplane layer BP1. A surface of the organic layer ORL may face the first surface SF1 of the base layer BSL, and another surface of the organic layer ORL may face a surface of the buffer layer BFL. In some embodiments, the surface of the organic layer ORL may contact the base layer BSL, and the another surface of the organic layer ORL may contact the surface of the buffer layer BFL.

In some embodiments, the organic layer ORL may be disposed between the base layer BSL and the first insulating layer INS1 (see FIG. 7). For example, the organic layer ORL may be included in the second backplane layer BP2. The surface of the organic layer ORL may face the second surface SF2 of the base layer BSL, and the another surface of the organic layer ORL may face a surface of the first insulating layer INS1. In some embodiments, the surface of the organic layer ORL may contact the base layer BSL, and the another surface of the organic layer ORL may contact the surface of the first insulating layer INS1.

Next, the light-emitting-element layer EML according to an embodiment will be described with reference to FIG. 8. FIG. 8 illustrates a schematic cross-sectional view of a display device according to an embodiment. FIG. 8 illustrates a cross-sectional structure of the display device 10 within the display area DA.

Referring to FIG. 8, the light-emitting-element layer EML may be disposed on the first backplane layer BP1.

The light-emitting-element layer EML may include the pixel electrodes PXE, the cathodes CE, and light emitting elements LE. Each of the first sub-pixel SPX1, the second sub-pixel SPX2, and the third sub-pixel SPX3 may include the light emitting element LE connected to the pixel electrode PXE and the cathode CE. According to an embodiment, the light emitting elements LE may include a first light emitting element LE1 that emits light of a first color and included in the first sub-pixel SPX1, a second light emitting element LE2 that emits light of a second color and included in the second sub-pixel SPX2, and a third light emitting element LE3 that emits light of a third color and included in the third sub-pixel SPX3. However, embodiments are not limited thereto. According to an embodiment, the first to third light emitting elements LE1, LE2, and LE3 may emit light of a same color, and a color filter layer and/or a quantum-dot layer may be further disposed on the light-emitting-element layer EML to provide a full-color display device 10.

The pixel electrode PXE may be referred to as an anode electrode, and the cathode CE may be referred to as a cathode electrode.

The pixel electrodes PXE and the cathode electrodes CE may be disposed on the first backplane layer BP1. Each of the pixel electrodes PXE may be connected (e.g., electrically connected) to the thin film transistor of the first backplane layer BP1. Accordingly, a pixel voltage or an anode voltage controlled by the thin film transistor may be applied to the pixel electrode PXE.

Each of the cathode electrodes CE may be connected (e.g., electrically connected) to a power wire formed on the first backplane layer BP1. Accordingly, a power voltage of the power wire may be applied to the cathode electrodes CE.

The pixel electrodes PXE and the cathode electrodes CE may include a highly reflective metallic material such as a stacked structure (Ti/Al/Ti) of aluminum and titanium, a stacked structure (ITO/Al/ITO) of aluminum and an ITO, an APC alloy, and a stacked structure (ITO/APC/ITO) of an APC alloy and an ITO. The APC alloy may be an alloy of silver (Ag), palladium (Pd), and copper (Cu).

FIG. 8 illustrates that each of the light emitting elements LE is a flip-chip type micro LED in which the first contact electrode CTE1 and the second contact electrode CTE2 are disposed to face the pixel electrode PXE and the cathode electrode CE. However, the shape of the light emitting element LE is not limited thereto.

The light emitting element LE may include an inorganic material such as GaN. A length in the first direction DR1, a length in the second direction DR2, and a length in the third direction DR3 of the light emitting element LE may be several μm to several hundred μm, respectively. For example, the length in the first direction DR1, the length in the second direction DR2, and the length in the third direction DR3 of the light emitting element LE may be about 100 μm or less, respectively.

Each light emitting element LE may be a light emitting structure/member including an n-type semiconductor NSEM, an active layer MQW, a p-type semiconductor PSEM, a first contact electrode CTE1, and a second contact electrode CTE2.

A portion of the n-type semiconductor NSEM may be disposed on the active layer MQW. A portion of the n-type semiconductor NSEM may be disposed on the second contact electrode CTE2. In some embodiments, a surface of the n-type semiconductor NSEM may face the display surface. The n-type semiconductor NSEM may be made of GaN doped with an n-type conductive dopant such as Si, Ge, or Sn. However, embodiments are not limited thereto.

The active layer MQW may be disposed on a portion of the surface of the n-type semiconductor NSEM. The active layer MQW may be interposed between the n-type semiconductor NSEM and the p-type semiconductor PSEM. The active layer MQW may include a material having a single quantum well structure or a multiple quantum well structure/member. In case that the active layer MQW includes a material having a multi-quantum well structure, well layers and a barrier layer may be alternately stacked. For example, the well layer may be formed of InGaN, and the barrier layer may be formed of GaN or AlGaN, but embodiments are not limited thereto. In another example, the active layer MQW may have a structure in which a semiconductor material having large band gap energy and a semiconductor material having small band gap energy are alternately stacked, or may include group 3 to group 5 semiconductor materials according to a wavelength band of light that emits light.

The p-type semiconductor PSEM may be disposed on a surface of the active layer MQW. The p-type semiconductor PSEM may be made of GaN doped with a p-type conductive dopant such as Mg, Zn, Ca, Se, or Ba. However, embodiments are not limited thereto.

The first contact electrode CTE1 may be disposed on the p-type semiconductor PSEM, and the second contact electrode CTE2 may be disposed on another portion of the surface of the n-type semiconductor NSEM. Another portion of the surface of the n-type semiconductor NSEM on which the second contact electrode CTE2 is disposed may be disposed to be spaced apart from a portion of the surface of the n-type semiconductor NSEM on which the active layer MQW is disposed.

The first contact electrode CTE1 and the pixel electrode PXE may be bonded to each other through a conductive adhesive member such as an anisotropic conductive film (ACF) or an anisotropic conductive paste (ACP). In another example, the first contact electrode CTE1 and the pixel electrode PXE may be bonded to each other through a soldering process.

For example, a bank BNK covering an edge portion of the pixel electrode PXE and an edge portion of the cathode electrode CE may be disposed on the first backplane layer BP1. The bank BNK may be formed as an organic film including an acryl resin, an epoxy resin, a phenolic resin, a polyamide resin, a polyimide resin, and the like.

An insulating film INS may be disposed on the bank BNK. The insulating film INS may cover an edge portion of the pixel electrode PXE and an edge portion of the cathode electrode CE. The insulating film INS may be formed as an inorganic film, for example, a silicon nitride layer, a silicon oxynitride layer, a silicon oxide layer, a titanium oxide layer, or an aluminum oxide layer.

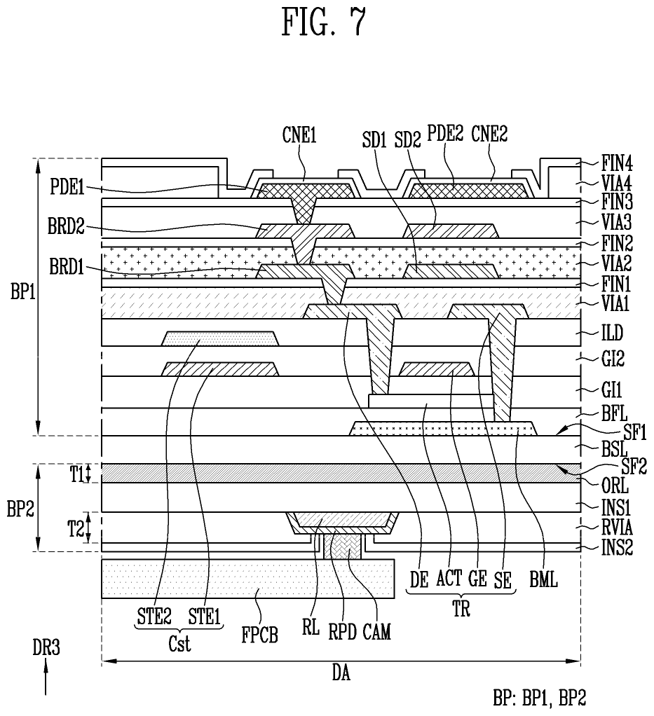

Hereinafter, a structure of a display device will be described with reference to FIG. 9 and FIG. 10. Descriptions that are redundant to those described above are simplified or are not repeated for descriptive convenience.

FIG. 9 illustrates a schematic cross-sectional view of a portion of a non-display area of a display device according to an embodiment. FIG. 10 illustrates a schematic cross-sectional view of a display area and a non-display area of a display device according to an embodiment.

Unlike the second backplane layer BP2 shown in FIG. 4, FIG. 6, and FIG. 7, the first backplane layer BP1 and the second backplane layer BP2 shown in FIG. 9 may be shown around the non-display area NDA.

The first backplane layer BP1 may include a buffer layer BFL, a front wire FL, a front pad electrode FPD, and insulating layers GI1, GI2, VIA1, VIA2, VIA3, FIN1, FIN2, FIN3, FIN4, and FIN4, which are disposed on the first surface SF1 of the base layer BSL.

The front pad electrode FPD may be disposed on the front wire FL to cover the front wire FL. The front pad electrode FPD may include a transparent conductive oxide. For example, the front pad electrode FPD may include an indium tin oxide (ITO), an indium zinc oxide (IZO), a zinc oxide (ZnO), an indium gallium zinc oxide (IGZO), and an indium tin zinc oxide (ITZO).

The front wire FL and the front pad electrode FPD may be connected (e.g., electrically connected) to the pixel circuit through other wires in the first backplane layer BP1.

The fourth front insulating layer FIN4 may be disposed on the front pad electrode FPD, the third front insulating layer FIN3, and the second gate insulating layer GI2 to cover the front pad electrode FPD, the third front insulating layer FIN3, and the second gate insulating layer GI2. The fourth front insulating layer FIN4 may cover the front pad electrode FPD so that at least a portion of the upper surface of the front pad electrode FPD may be exposed. The fourth front insulating layer FIN4 may be an inorganic insulating layer including an inorganic material.

The second backplane layer BP2 may include the first insulating layer INS1, the rear wire RL, the rear pad electrode RPD, the rear via layer RVIA, and the second insulating layer INS2, which are disposed on the second surface SF2 of the base layer BSL.

The rear pad electrode RPD may be disposed to cover the rear wire RL, the first insulating layer INS1, and the base layer BSL so as to cover at least a portion of the rear wire RL, at least a portion of the first insulating layer INS1, and a portion of the base layer BSL.

The rear via layer RVIA may be disposed on the rear wire RL, and may be disposed to cover at least a portion of the rear wire RL and the rear pad electrode RPD.

The second insulating layer INS2 may be disposed on the rear via layer RVIA, and may be disposed to partially cover the rear via layer RVIA and the rear pad electrode RPD.

Referring to FIG. 10, the display device according to an embodiment may include a side wire SL for connecting (e.g., electrically connecting) a wire, a pad electrode, and the like disposed on the first surface SF1 and the second surface SF2 of the base layer BSL, and may further include an overcoat layer OC for protecting a wire, a pad electrode, and the like of the non-display area NDA.

The side wire SL may be disposed to cover the first surface SF1 and the second surface SF2 of the base layer BSL and a side surface of the base layer BSL. Accordingly, the side wire SL may connect (e.g., electrically connect) the front wire FL, the front pad electrode FPD, and the like that are disposed on the first surface SF1 to the rear wire RL, the rear pad electrode RPD, and the like that are disposed on the second surface SF2.

The overcoat layer OC may be disposed to cover the side wire SL and to cover the first surface SF1 and the second surface SF2 of the base layer BSL and a side surface of the base layer BSL. The overcoat layer OC may include at least one of an acrylic resin, an epoxy resin, a phenol resin, a polyamide resin, and a polyimide resin. However, embodiments are not limited thereto.

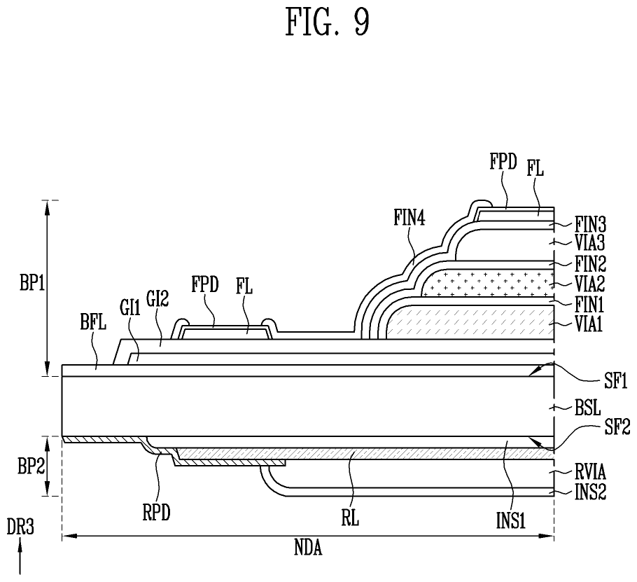

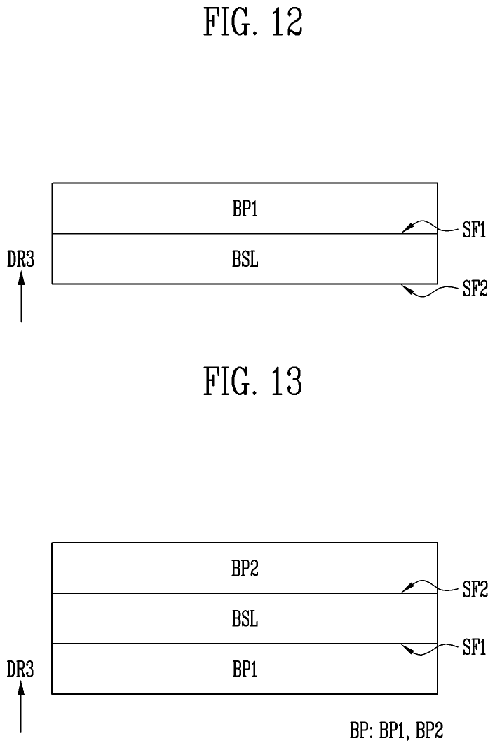

Hereinafter, a method of manufacturing the display device 10 according to an embodiment will be described with reference to FIG. 11 to FIG. 17. Descriptions that are redundant to those described above are simplified or are not repeated for descriptive convenience.

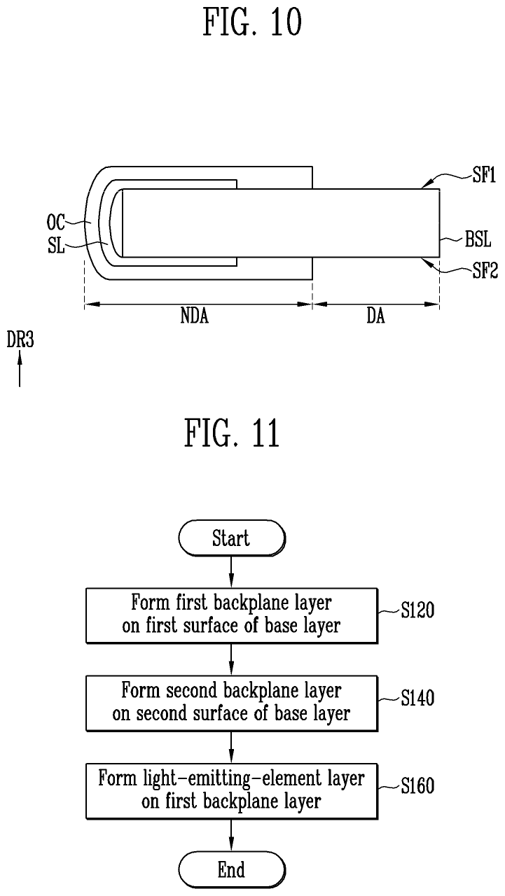

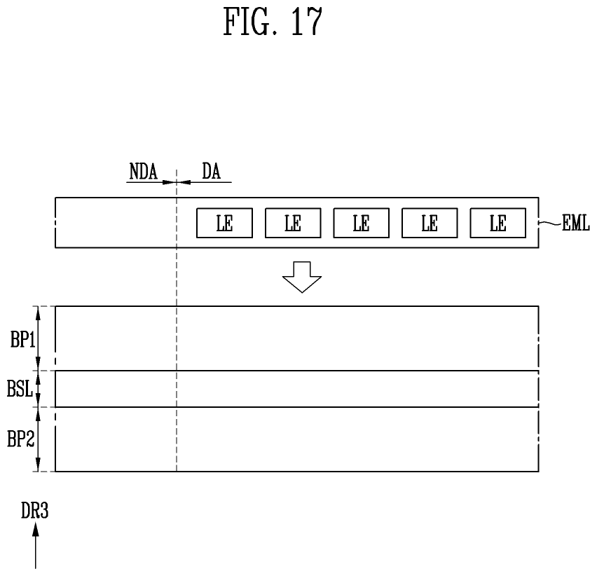

FIG. 11 illustrates a flowchart of a method of manufacturing the display device according to an embodiment. FIG. 12 to FIG. 17 illustrate cross-sectional views of process phases/steps of a method of manufacturing the display device according to an embodiment. FIG. 12 to FIG. 16 may schematically illustrate a process phase/step of forming the backplane layer BP on the base layer BSL. FIG. 17 may schematically illustrate a phase/step of forming the light-emitting-element layer EML on the first backplane layer BP1.

Referring to FIG. 11, a method of manufacturing the display device 10 according to an embodiment may include forming the first backplane layer on the first surface of the base layer (S120), forming the second backplane layer on the second surface of the base layer (S140), and forming the light-emitting-element layer on the first backplane layer (S160).

Referring to FIG. 11 and FIG. 12, in a phase/step S120 of forming the first backplane layer on the first surface of the base layer, the base layer BSL may be prepared and the first backplane layer BP1 may be formed (or disposed) on the first surface SF1 of the base layer BSL.

In this phase/step, the base layer BSL may be prepared, and conductive layers and insulating layers for forming the backplane layer BP may be patterned on the base layer BSL. For example, the conductive layers and the insulating layers may be formed through a typical patterning process (for example, a photolithography process) by using a mask.

In this phase/step, the conductive layers and the insulating layers may be patterned to form the first backplane layer BP1 on the first surface SF1 of the base layer BSL. For example, the lower metal layer BML, the transistor TR, the storage capacitor Cst, the first bridge electrode BRD1, the first data electrode SD1, the second bridge electrode BRD2, the second data electrode SD2, the first pixel electrode PDE1, the second pixel electrode PDE2, the first connection electrode CNE1, the second connection electrode CNE2, and insulating layers BFL, GI1, GI2, ILD, VIA1, VIA2, VIA3, VIA4, FIN1, FIN2, FIN3, and FIN4 may be formed on the base layer BSL. For example, a pixel circuit (for example, the transistor TR) may be formed on the first surface SF1 of the base layer BSL.

In some embodiments, a separate cutting process (for example, a laser lift-off process) may not be performed on the base layer BSL. For example, the base layer BSL may be a substrate for manufacturing the backplane layer BP, and may form a base member of the display device 10 manufactured without performing a laser lift-off process.

Experimentally, laser light including the UV wavelength band may be used to perform the laser lift-off process. According to an embodiment, the base layer BSL may non-transmit at least some of the UV light, so that the base layer BSL for forming the backplane layer BP may not be substantially cut to form the base of the display device 10.

In this phase/step, the second surface SF2 of the base layer BSL may face downward based on the gravity direction.

In some embodiments, in case that the organic layer ORL is included in the first backplane layer BP1 and manufactured, the organic layer ORL may be formed in case that the first backplane layer BP1 is manufactured. For example, the organic layer ORL may be disposed on the first surface SF1 of the base layer BSL, and the buffer layer BFL may be formed after the organic layer ORL is disposed.

Referring to FIG. 11 to FIG. 16, in a phase/step S140 of forming the second backplane layer on the second surface of the base layer, the second backplane layer BP2 may be formed (or disposed) on the second surface SF2 of the base layer BSL.

In this phase/step, the stacked structure including the base layer BSL and the first backplane layer BP1 may be reversed. For example, the first surface SF1 of the base layer BSL may face downward based on the direction of gravity, and thus the first backplane layer BP1 may face downward based on the direction of gravity, and the second surface SF2 of the base layer BSL may form a base for patterning the second backplane layer BP2.

In this phase/step, the conductive layers and the insulating layers may be patterned to form the second backplane layer BP2 on the second surface SF2 of the base layer BSL. For example, the rear wire RL, the rear pad electrode RPD, the first insulating layer INS1, the second insulating layer INS2, and the rear via layer RVIA may be formed on the base layer BSL.

According to an embodiment, since a rear surface process for forming the second backplane layer BP2 may be performed by changing the pose (or position) of the base layer BSL, process equipment and process materials for forming the first backplane layer BP1 may be used.

According to an embodiment, referring to FIG. 14, the first insulating layer INS1 may be formed on the second surface SF2 of the base layer BSL, and the rear wire RL may be patterned on the first insulating layer INS1.

For example, the rear wire RL may be manufactured by depositing a base electrode for patterning the rear wire RL and etching the deposited base electrode. In some embodiments, the base electrode may be an electrode layer including aluminum.

For example, the base electrode may include a multi-layered structure/member including a titanium layer, an aluminum layer, and a titanium layer. For example, the base electrode may be etched to manufacture the rear wire RL including a titanium layer (for example, the first layer L1), an aluminum layer (for example, the second layer L2), and a titanium layer (for example, the third layer L3).

In some embodiments, a physical vapor deposition (PVD) process (for example, a sputtering process), a chemical vapor deposition (CVD) process, an atomic layer deposition (ALD) process, and the like may be used to deposit the base electrode.

In this phase/step, in order to etch the base electrode, a dry etching process using plasma (PLSA) may be performed. For example, in order to etch the base electrode, a dry etching process using Cl₂ plasma (PLSA) may be performed. In some embodiments, the dry etching process using the Cl₂ plasma (PLSA) may be suitable for etching an aluminum layer.

In this phase/step, in case that the dry etching process using the plasma (PLSA) is performed, UV light may occur. As described above, UV light may be emitted within/on the first insulating layer INS1, and in case that the rear wire RL includes aluminum, UV light may be emitted during the process of forming the rear wire RL.

For example, the base layer BSL may non-transmit at least a portion of UV light, and a risk due to application of UV light to the first backplane layer BP1 (for example, the transistor TR) may be reduced.

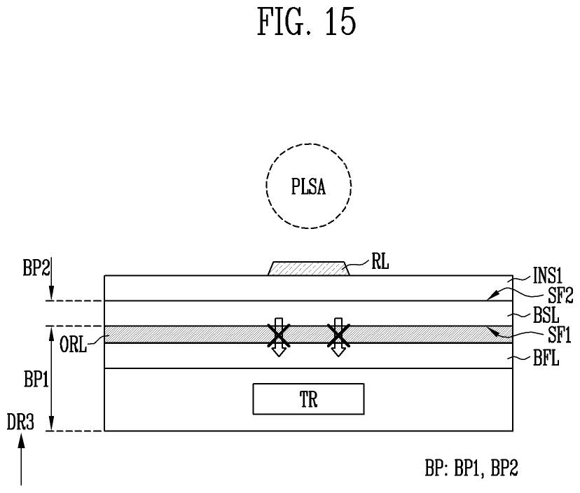

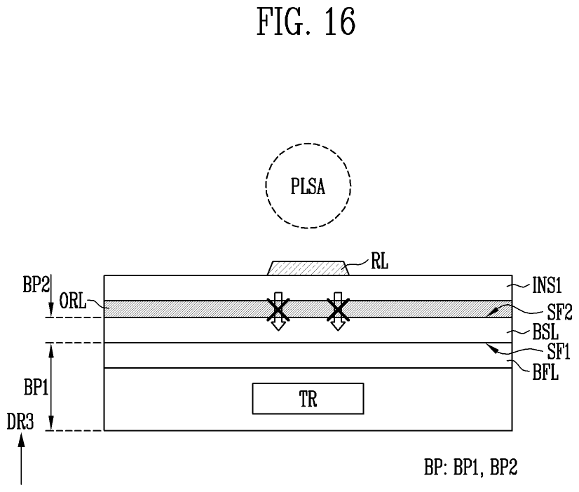

As another example, the organic layer ORL may be formed between the transistor TR and the rear wire RL. The organic layer ORL may be manufactured in case that the first backplane layer BP1 is formed and disposed between the base layer BSL and the buffer layer BFL (FIG. 15), and in some embodiments, the organic layer ORL may also be manufactured in case that the second backplane layer BP2 is formed and disposed between the base layer BSL and the first insulating layer INS1 (FIG. 16). The organic layer ORL may non-transmit at least a portion of UV light, and a risk due to application of UV light to the first backplane layer BP1 (for example, the transistor TR) may be reduced.

In some embodiments, the base electrode for manufacturing the rear wire RL may be an electrode layer that does not include aluminum. For example, the base electrode may include a multi-layered structure/member including a titanium layer, a copper layer, and a titanium layer. For example, the base electrode may be etched to manufacture the rear wire RL including a titanium layer (for example, the first layer L1), a copper layer (for example, the second layer L2), and a titanium layer (for example, the third layer L3). In another example, the base electrode may include a multi-layered structure/member including a titanium layer, a molybdenum layer, and a titanium layer. For example, the base electrode may be etched to manufacture the rear wire RL including a titanium layer (for example, the first layer L1), a molybdenum layer (for example, the second layer L2), and a titanium layer (for example, the third layer L3).

For example, a dry etching process may be performed to pattern the rear wire RL. In case that the dry etching process is used, a plasma (PLSA) dry etching process may not be performed in case that the second backplane layer BP2 is manufactured. For example, the risk of UV light emission due to the formation of the aluminum layer may be eliminated, and the risk of UV light emission may be eliminated in the first insulating layer INS1 and the buffer layer BFL. Accordingly, the risk of UV light being applied to the first backplane layer BP1 may be reduced.

For example, as the plasma (PLSA) dry etching process is not performed, the risk of excessively trapping holes in the buffer layer BFL may be eliminated. For example, as described above, since the threshold voltage of the transistor TR may be shifted, a difference in luminance may occur between some areas within the display area DA. However, according to an embodiment, as a dry etching process is used to pattern the rear wire RL, the aforementioned risk may be eliminated.

In some embodiments, the rear pad electrode RPD may be patterned on the rear wire RL, and the rear via layer RVIA and the second insulating layer INS2 may be patterned. For example, a side process of disposing the driving circuit portion FPCB on the second backplane layer BP2 and connecting (e.g., electrically connecting) the driving circuit portion FPCB to the wire in the first backplane layer BP1 through the rear pad electrode RPD and the rear wire RL may be performed. For example, the wire in the second backplane layer BP2 and the wire in the first backplane layer BP1 may be connected (e.g., electrically connected) by disposing the side wire SL covering the side surface of the base layer BSL.

Referring to FIG. 11 and FIG. 17, in a phase/step S160 of forming the light-emitting-element layer on the first backplane layer BP1, the light emitting elements LE may be disposed on the first backplane layer BP1.

In some embodiments, the stacked structure including the base layer BSL, the first backplane layer BP1, and the second backplane layer BP2 may be reversed so that the first backplane layer BP1 faces upward based on the gravity direction before this phase/step may be performed.

In this phase/step, an area in which the light emitting elements LE are disposed may be defined as the display area DA, and an area in which the light emitting elements LE are not disposed may be defined as the non-display area NDA.

In this phase/step, the light emitting elements LE may be transferred onto the first backplane layer BP1 in various methods. For example, the light emitting elements LE may be transferred by using one or more of devices using one or more of a transfer method using a stamp, a transfer method using a laser, a transfer method using electrostatic force, a transfer method using magnetic force and electromagnetic force, and a transfer method using adhesive. However, embodiments are not limited to specific examples.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a base layer including a first surface and a second surface;
a first backplane layer disposed on the first surface of the base layer and including a pixel circuit;
a second backplane layer disposed on the second surface of the base layer and including a rear wire; and
a light-emitting-element layer disposed on the first backplane layer and including a light emitting element,
wherein the base layer has a transmittance of about 15% or less with respect to light having a wavelength of about 290 nm or less.

2. The display device of claim 1, further comprising:
a driving circuit portion electrically connected to the rear wire;
a front wire disposed on the first surface of the base layer; and
a side wire covering a side surface of the base layer and electrically connected to the front wire and the rear wire.

3. The display device of claim 2, wherein the rear wire includes a multi-layered member including an aluminum layer.

4. The display device of claim 1, wherein the base layer includes borosilicate glass doped with a dopant.

5. The display device of claim 1, wherein the base layer has a transmittance of about 10% or less with respect to light having a wavelength of about 290 nm or less.

6. A display device comprising:
a base layer including a first surface and a second surface;
a first backplane layer disposed on the first surface of the base layer and including a pixel circuit;
a second backplane layer disposed on the second surface of the base layer and including a rear wire; and
a light-emitting-element layer disposed on the first backplane layer and including a light emitting element,
wherein the first backplane layer is disposed between the pixel circuit and the rear wire and includes an organic layer having a transmittance of about 10% or less with respect to light having a wavelength of about 290 nm or less.

7. The display device of claim 6, wherein the organic layer includes polyimide.

8. The display device of claim 6, wherein
the first backplane layer further includes a buffer layer disposed between the pixel circuit and the base layer, and
the organic layer is disposed between the buffer layer and the base layer.

9. The display device of claim 6, wherein
the second backplane layer further includes an insulating layer disposed between the rear wire and the base layer, and
the organic layer is disposed between the insulating layer and the base layer.

10. The display device of claim 6, wherein
the second backplane layer further includes a rear via layer that is disposed on the base layer and covers a portion of the rear wire,
the organic layer has a first thickness,
the rear via layer has a second thickness, and
the second thickness is greater than the first thickness.

11. The display device of claim 10, wherein the first thickness is about 0.5 μm to about 2.0 μm.

12. A method of manufacturing a display device, the method comprising:
preparing a base layer including a first surface and a second surface;
forming a first backplane layer on the first surface of the base layer; and
forming a second backplane layer on the second surface of the base layer, wherein the base layer has a transmittance of about 15% or less with respect to light having a wavelength of about 290 nm or less.

13. The method of manufacturing the display device of claim 12, further comprising:
after forming the first backplane layer, reversing the base layer and the first backplane layer such that the first surface of the base layer faces downward based on a direction of gravity.

14. The method of manufacturing the display device of claim 12, wherein the forming of the first backplane layer includes:
disposing a buffer layer on the first surface of the base layer; and
forming a transistor including a semiconductor layer on the buffer layer.

15. The method of manufacturing the display device of claim 12, wherein
the forming of the second backplane layer includes:
forming an insulating layer on the second surface of the base layer; and
forming a rear wire on the insulating layer, and
the forming of the rear wire includes performing a dry etching process by using Cl₂ plasma.

16. The method of manufacturing the display device of claim 15, wherein the performing of the dry etching process includes emitting UV light on the insulating layer.

17. The method of manufacturing the display device of claim 16, wherein the base layer does not transmit at least a portion of the UV light emitted on the insulating layer.

18. The method of manufacturing the display device of claim 12, wherein
the forming of the second backplane layer includes:
forming an insulating layer on the second surface of the base layer; and
forming a rear wire on the insulating layer, and
the forming of the rear wire includes performing a wet etching process.

19. The method of manufacturing the display device of claim 12, wherein the forming of the first backplane layer includes:
disposing an organic layer on the first surface of the base layer, and
disposing a buffer layer on the organic layer.

20. The method of manufacturing the display device of claim 12, wherein the forming of the second backplane layer includes:
disposing an organic layer on the second surface of the base layer, and
disposing an insulating layer on the organic layer.
